(19) United States
(12) Patent Application Publication
(10) Pub. No.: US 2002/0045318 A1
(43) Pub. Date: Apr. 18, 2002

(54) METHOD FOR MANUFACTURING MOS TRANSISTOR

(76) Inventors: COMING CHEN, TAOYUAN HSIEN (TW); WATER LUR, TAIPEI (TW)

Correspondence Address: J.C. PATENTS, INC., 4 VENTURE, SUITE 250, IRVINE, CA, 92618, US

(21) Appl. No.: 09/303,322

(22) Filed: Apr. 30, 1999

(51) Int. Cl. H01L 21/336

(52) U.S. Cl. 438/303; 438/305

(57) ABSTRACT

A method for manufacturing a MOS transistor. The method includes the steps of providing a substrate having a gate electrode thereon, and then depositing a first dielectric material over the gate electrode and the substrate to form a conformal first dielectric layer. Next, spacers are formed over the first dielectric on the sidewalls of the gate electrode. Thereafter, a portion of the first dielectric layer is removed by performing an isotropic etching operation. Ultimately, a portion of the first dielectric layer between the spacers and the gate electrode as well as between the spacers and the substrate are removed. Finally, a second dielectric material is deposited over the gate electrode forming voids in the space between the gate electrode and the spacer as well as between the substrate and the spacer.

### BACKGROUND OF THE INVENTION

1. Field of Invention

The present invention relates to a method for manufacturing a MOS transistor. More particularly, the present invention relates to a method for manufacturing a MOS transistor that can minimize gate-to-drain parasitic capacitance.

2. Description of Related Art

Conventionally, oxide material is deposited over the substrate after MOS transistors are formed in a substrate. The oxide material, which has a dielectric constant of between 3.8 to 4.0, is used for electrical isolation. However, as the dimensions of a device continue to shrink and faster data transmission devices are in great demand, simply using a layer of oxide material to isolate the gate terminal from the drain terminal becomes ineffective. Consequently, gate-to-drain parasitic capacitance may rise leading to a functionally defective electrical device.

### SUMMARY OF THE INVENTION

The invention provides a method for manufacturing a MOS transistor. The method includes the steps of providing a substrate having a gate electrode thereon, and then forming a conformal first dielectric layer over the gate electrode and the substrate. Next, spacers are formed over the first dielectric on the sidewalls of the gate electrode. Thereafter, the exposed first dielectric layer and a portion of the first dielectric layer underneath the spacers are removed. Finally, a second dielectric layer is formed over the gate electrode, the spacers and the substrate.

According to the preferred embodiment of this invention, the first dielectric layer is formed using a material that differs from the material for forming the spacers. The first dielectric layer is formed by depositing oxide, whereas the spacers are formed by depositing silicon nitride. In addition, the exposed first dielectric layer and a portion of the first dielectric layer underneath the spacers are removed using an isotropic etching operation.

The method of the invention forms voids in the space between the spacers and the substrate as well as between the spacers and the gate electrode. These voids contain air, and thus provide a medium with a low dielectric constant. In fact, the dielectric constant within the voids is far lower than the dielectric constant of the second dielectric layer. By using a low dielectric constant medium to isolate the gate electrode from the source/drain regions, the peripheral electric field between the gate electrode and a source/drain region are lowered. Hence, the problem caused by gate-to-drain parasitic capacitance can be prevented.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIGS. 1A through 1C are cross-sectional views showing the progression of manufacturing steps in fabricating a MOS transistor according to one preferred embodiment of this invention.

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

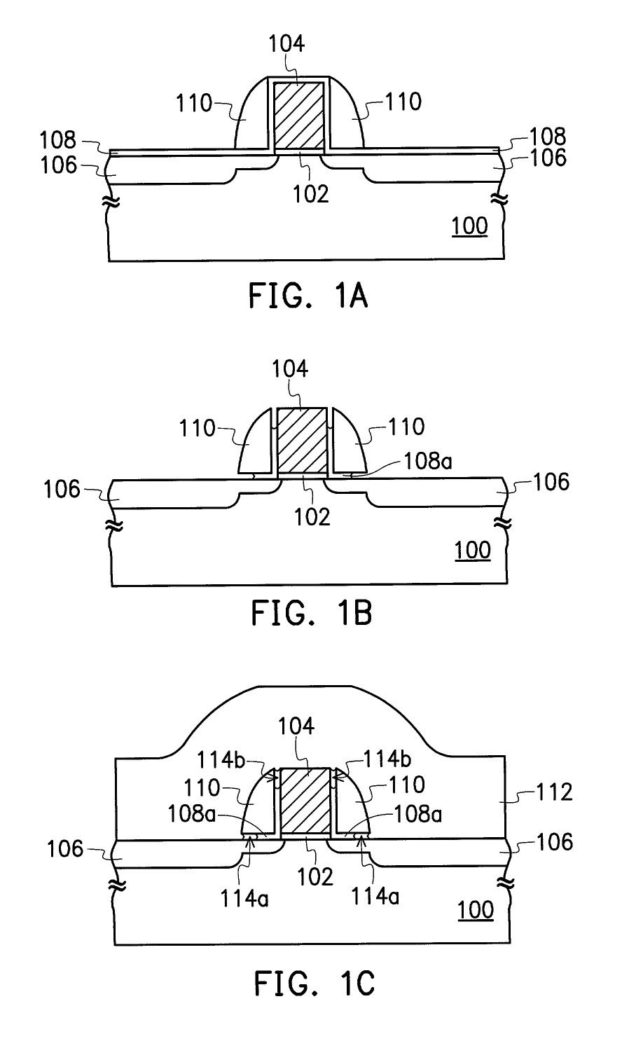

FIGS. 1A through 1C are cross-sectional views showing the progression of manufacturing steps in fabricating a MOS transistor according to one preferred embodiment of this invention.

As shown in FIG. 1A, a substrate 100 such as a semiconductor silicon substrate is provided. A patterned gate oxide layer 102, a gate electrode 104, source/drain regions 106, a conformal dielectric layer 108 and spacers 110 are sequentially formed over the substrate 100. The method includes implanting ions into the substrate 100, with the gate electrode 104 serving as a mask, to form lightly doped regions on both sides of the gate electrode 104 after the gate oxide layer 102 and the gate electrode 104 are patterned. Thereafter, a conformal dielectric layer 108 is formed over the gate electrode 104 and the substrate 100. Subsequently, spacers 110 are formed over the dielectric layer 108 on the sidewalls of the gate electrode 104. Next, a second ion implantation is carried out, with the gate electrode 104 and the spacers 110 serving as a mask, to form heavily doped regions in the substrate 100 on both sides of the gate electrode 104. The lightly doped and heavily doped regions together form the source/drain regions 106. The gate electrode 104 can be formed by depositing polysilicon, amorphous silicon or other material having similar properties. The spacers 110 are formed using a material that differs from the material for forming the dielectric layer 108. For example, the dielectric layer 108 can be an oxide layer, whereas the spacer can be a silicon nitride layer.

As shown in FIG. 1B, an isotropic etching operation is carried out to remove a portion of the dielectric layer 108 and to form a dielectric layer 108a. After the isotropic etching operation, a portion of the substrate 100 and the upper surface of the gate electrode 104 are exposed. Furthermore, a portion of the dielectric layer 108 between the spacers 110 and the substrate 100 as well as between the spacers 110 and the gate electrode 104 are removed, forming some recess cavities. Consequently, a portion of the sidewalls between the spacers 110 and the gate electrode 104 as well as a portion of the substrate 100 underneath the spacers 110 are exposed. The isotropic etching operation can be conducted using an etchant such as hydrofluoric acid solution.

As shown in FIG. 1C, another dielectric material is deposited over the gate electrode 104 and the substrate 100 to form a dielectric layer 112. The dielectric layer 112 can be an oxide layer. When the dielectric material is deposited over the substrate 100, the recess cavities between the gate electrode 104, the substrate 100 and the spacers 110 may not be entirely filled. Some of the recess cavities may be enclosed forming voids 114b in the space between the spacers 110 and the gate electrode 104. Similarly, voids 114a may also be formed in the space between the spacers 110 and the substrate 100.

In general, voids 114a and 114b are filled with air that has a dielectric constant of about 1.0. This is far below the dielectric constant of the dielectric layer 112. With the inclusion of voids in the dielectric material, the dielectric constant of the dielectric layer is lowered considerably. Hence, gate-to-drain parasitic capacitance can be reduced and the operating speed of the device can be increased.

In summary, the characteristic of the invention includes:

1. By planting voids between the gate electrode and the spacers as well as underneath the spacer of a MOS transistor, the dielectric constant of the dielectric layer between the gate electrode and the source/drain region is decreased. Hence, the peripheral electric field between the gate electrode and the source/drain region is lowered.

2. Because air inside the voids has a dielectric constant of about 1.0, the dielectric constant of the material between the gate electrode and the source/drain regions is decreased. Hence, gate-to-drain parasitic capacitance is also reduced. It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A method of manufacturing a MOS transistor, comprising the steps of:
providing a substrate having a gate electrode thereon;
forming a first dielectric layer over the gate electrode and the substrate conformal to the surface of the gate electrode and the substrate;
forming spacers over the first dielectric layer on the sidewalls of the gate electrode;
removing a portion of the first dielectric layer such that a portion of the first dielectric layer underneath the spacers is also removed; and
depositing dielectric material over the gate electrode and the substrate to form a second dielectric layer.

2. The method of claim 1, wherein before the step of forming the conformal first dielectric layer over the gate electrode and the substrate, further includes performing an ion implantation operation, with the gate electrode serving as a mask, to form a first doped region in the substrate.

3. The method of claim 2, wherein after the step of forming the spacers, further includes performing an ion implantation operation, with the gate electrode and the spacers serving as a mask, to form a second doped region in the substrate.

4. The method of claim 1, wherein the first dielectric layer is formed using a material that differs from the material for forming the spacers.

5. The method of claim 4, wherein the step of forming the first dielectric layer includes depositing oxide material and the step of forming the spacers includes depositing silicon nitride.

6. The method of claim 1, wherein the step of removing a portion of the first dielectric layer includes using an isotropic etching operation.

7. The method of claim 6, wherein the step of removing a portion of the first dielectric layer further includes etching away a portion of the first dielectric layer between the gate electrode and the spacers.

8. The method of claim 6, wherein the step of performing the isotropic etching operation includes etching with hydrofluoric acid solution.

9. A method for manufacturing a MOS transistor, comprising the steps of:
providing a substrate having a gate electrode thereon and a first doped region in the substrate on each side of the gate electrode;
forming a first dielectric layer over the gate electrode and the substrate conformal to the surface of the gate electrode and the substrate;
forming spacers over the first dielectric layer on the sidewalls of the gate electrode;
forming a second doped region in the substrate with the gate electrode and the spacers serving as a mask;
removing a portion of the first dielectric layer so that a portion of the substrate underneath the spacers and a portion of the gate electrode and spacer sidewalls are exposed; and
depositing dielectric material over the gate electrode to form a second dielectric layer, hence forming voids between the spacers and the substrate as well as between the spacers and the gate electrode.

10. The method of claim 9, wherein the first dielectric layer is formed using a material that differs from the material for forming the spacers.

11. The method of claim 10, wherein the step of forming the first dielectric layer includes depositing oxide material and the step of forming the spacers includes depositing silicon nitride.

12. The method of claim 9, wherein the step of removing a portion of the first dielectric layer includes using an isotropic etching operation.

13. The method of claim 12, wherein the step of performing the isotropic etching operation includes etching with hydrofluoric acid solution.
